(19) United States
(12) Patent Application Publication
(10) Pub. No.: US 2014/0225172 A1
(43) Pub. Date: Aug. 14, 2014

(54) Image Sensor with IR Filter

(71) Applicant: Kuo-Ching CHIANG, New Taipei City (TW)

(72) Inventor: Kuo-Ching CHIANG, New Taipei City (TW)

(21) Appl. No.: 13/762,399

(22) Filed: Feb. 8, 2013

(51) Int. Cl. H01L 27/146

(52) U.S. Cl. CPC H01L 27/14643; B82Y 20/00
USPC 257/292; 977/742

(57) ABSTRACT

The image sensor comprises a substrate; and a MOS having gate dielectric layer, a source, a drain and a gate. The MOS is formed over the substrate; a photo-diode doped region is formed adjacent to the MOS, at least one isolation layer is laminated over the photo-diode doped region and at least one conductive pattern is formed within the at least one isolation layer; and a carbon nano-tube layer is formed over the at least one isolation layer to act as an infrared ray filter. The conductive pattern is formed with carbon nano-tube to increase fill factor. The at least one conductive pattern further includes conductive polymer. Lens is formed over the at least one isolation layer to guide incident light into the photo-diode doped region.

### TECHNICAL FIELD

The present invention is generally related to image sensor, more particularly, the present invention is directed to a image sensor having a carbon nanotube coating.

### BACKGROUND OF THE RELATED ART

Complementary Metal Oxide Semiconductor (CMOS) image sensors are typically formed on a silicon substrate. CMOS image sensors are typically sensitive to infrared ray. As a result, certain wavelengths of infrared light will degrade sensor detection, therefore, an infrared filter is provided for CMOS image sensors. However, the additional filter will enlarge the size of the device. Another disadvantage of an image sensor is that the fill factor is not so high, where the fill factor is the percentage of the pixel area sensitive to light. In particular, the metal lines of the interconnection regions can block some of the light from reaching photodiodes, thereby reducing the fill factor. Therefore, in light of the above-described problems, the apparatus and method of the present invention was developed.

### SUMMARY

The image sensor comprises a substrate; and a MOS having gate dielectric layer, a source, a drain and a gate. The MOS is formed over the substrate; a photo-diode doped region is formed adjacent to the MOS, at least one isolation layer is laminated over the photo-diode doped region and at least one conductive pattern is formed within the at least one isolation layer; and a carbon nano-tube layer is formed over the at least one isolation layer to act as an infrared ray filter. The conductive pattern is formed with carbon nano-tube to increase fill factor. The at least one conductive pattern further includes conductive polymer. Lens is formed over the at least one isolation layer to guide incident light into the photo-diode doped region.

The image sensor comprises a substrate; a MOS having gate dielectric layer, a source, a drain and a gate, the MOS is formed over the substrate; a photo-diode doped region formed adjacent to the MOS. At least one isolation layer is laminated over the photo-diode doped region; At least one conductive pattern is formed within the at least one isolation layer; and lens formed over the at least one isolation layer to guide incident light into the photo-diode doped region; A carbon nano-tube layer is formed over the lens to act as an infrared ray filter. The at least one conductive pattern is formed with carbon nano-tube to increase fill factor. The at least one conductive pattern further includes conductive polymer.

The image sensor comprises a substrate and a MOS formed over the substrate; a photo-diode doped region is formed adjacent to the MOS, at least one first isolation layer is laminated under the substrate; at least one conductive pattern is formed within the at least one first isolation layer; and at least one second isolation layer formed over the photo-diode doped region; a carbon nano-tube layer formed over the at least one second isolation layer to act as an infrared ray filter. The at least one conductive pattern is formed with carbon nano-tube to increase fill factor. The at least one conductive pattern further includes conductive polymer. The image sensor further comprises lens formed over the at least one isolation layer to guide incident light into the photo-diode doped region.

The image sensor comprises a substrate and a MOS, a photo-diode doped region is formed adjacent to the MOS. At least one first isolation layer is laminated under the substrate; at least one conductive pattern is formed within the at least one first isolation layer; and at least one second isolation layer formed over the photo-diode doped region; lens formed over the at least one isolation layer to guide incident light into the photo-diode doped region; a carbon nano-tube layer formed over the lens to act as an infrared ray filter. The at least one conductive pattern is formed with carbon nano-tube to increase fill factor. The at least one conductive pattern further includes conductive polymer.

### BRIEF DESCRIPTION OF THE DRAWINGS

The invention is more fully appreciated in connection with the following detailed description taken in conjunction with the accompanying drawings, in which:

FIG. 1 illustrates an image sensor in accordance with the present invention; and

FIG. 2 illustrates an image sensor in accordance with the present invention.

### DETAILED DESCRIPTION

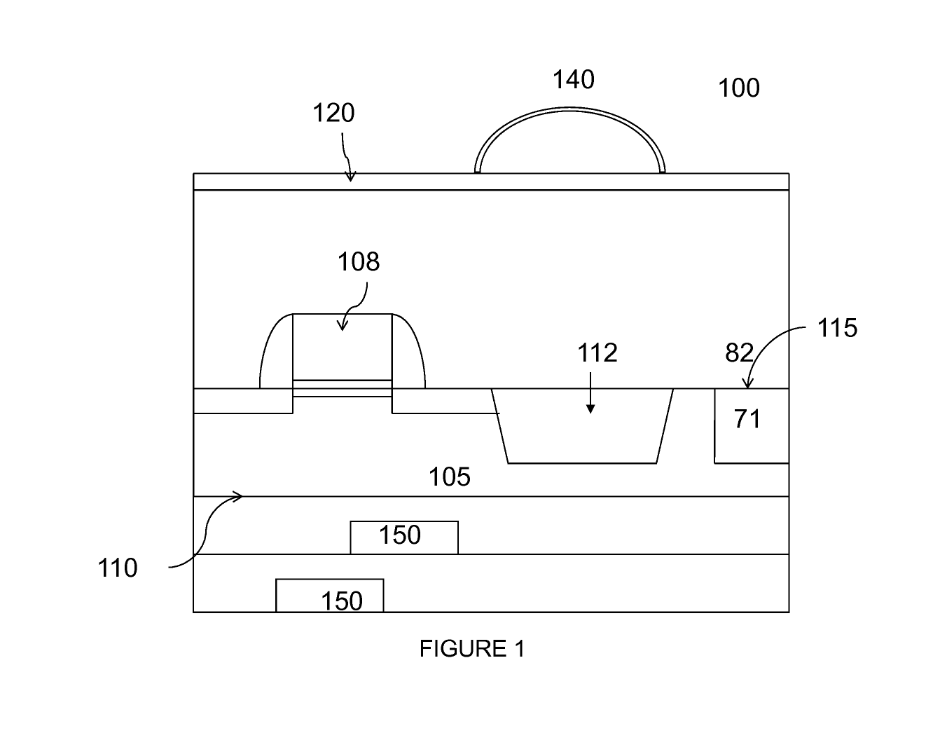

FIG. 1 illustrates an image sensor 100 in accordance with one embodiment of the present invention. In one embodiment, a CMOS image sensor formed on epitaxial silicon. A semiconductor substrate 105 has a front surface 110 and a back surface 115. An array of photo-sensitive pixels 112 and MOS 108 are formed in and on the substrate 105. After front-side processing is completed the semiconductor wafer is thinned down, the thickness of substrate 105 after the backside is ten microns or less. An infrared ray filtering coating 120 is employed, one example, carbon nanotube (CNT), graphene or the combination is used as the transparent conductive coating 120 is formed on the backside 115 of the substrate 105 to act as an infrared ray filter to omit additional filter. A color filter array maybe necessary, micro-lens 140 is fabricated over top of CNT 120. The graphene is another alternative for the IR filter coating. The micro-lens 140 serves to focus light into individual pixels.

An exemplary film thickness of the CNT is less than ten microns. Exemplary types of CNTs such as single walled CNTs, double walled CNTs, and multi-walled CNTs. The electrical and optical properties of CNT will thus depend on its thickness, CNT diameter. A conductive wiring pattern 150 is formed under the array of photo-sensitive pixels 112. If the CNT transparent coating 120 is employed, the additional IR filter is not required. The CNT transparent coating 120 maybe formed under the lens 140 or over the lens 140. The IR filtering coating is formed with CNT, graphene or the combination. The at least one conductive pattern 150 is formed with carbon nano-tube, graphene or the combination. In one example, the IR filtering coating layer is reduced graphene oxide which can strongly absorb infrared radiation. Graphene is a single, flat sheet of carbon arranged in a honeycombed lattice. The free electrons in graphene behave like relativistic particles with no rest mass, they passes through the material at extremely high speeds. Please refer to Journal of Chemistry, Volume 2013 (2013), Article ID 150536, 6 pages, entitled “Synthesis and Characterization of Graphene Thin Films by Chemical Reduction of Exfoliated and Intercalated Graphite Oxide”. The graphite was subjected to an oxidative treatment with potassium permanganate (KMnO₄) in concentrated sulphuric acid (H₂SO₄). Natural flake graphite powder (2.0 g) was weighed and placed in a round bottom flask, 46 mL of concentrated sulphuric acid was added and the mixture cooled in an ice bath, and 6.0 g of potassium permanganate (KMnO₄) was gradually added over a period of 30 min with continuous stirring. The mixture was stirred at 35° C. for 2 hours, then 92 mL of distilled water was slowly added to the mixture, and the temperature was maintained below 100° C. for 15 min. Finally, 280 mL of 30% hydrogen peroxide (H₂O₂) solution was added to the mixture. The product was finally filtered with 500 mL of 10% hydrochloric acid (HCl) solution to remove metal ions and then thoroughly washed with distilled water. A solution of hydrazine hydrate (H₂O₄) that weighed 10% of the GO dispersed in water was added as a reducing agent and stirred for 3 hrs. Another method for forming the graphene may refer to “Synthesis of graphene-based nanosheets via chemical reduction of exfoliated graphite oxide”, by Sasha Stankovich et al., Carbon, Volume 45, Issue 7, June 2007, Pages 1558-1565. Mark P. Levendorf disclosed “Transfer-Free Batch Fabrication of Single Layer Graphene Transistors”, Nano Lett., 2009, 9 (12), pp 4479-4483, Publication Date (Web): Oct. 27, 2009.

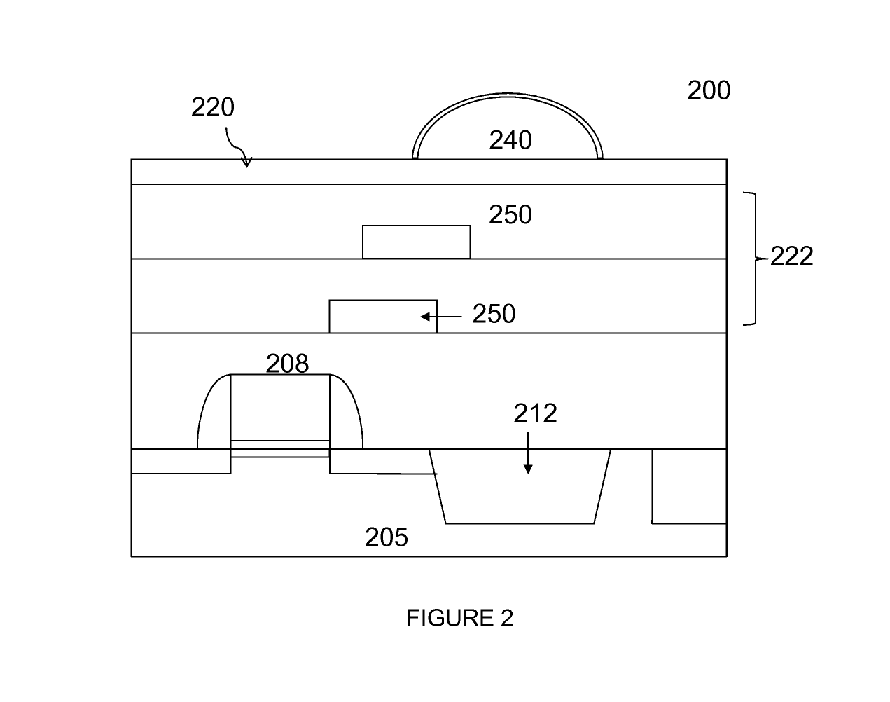

Another example is illustrated in FIG. 2, the image sensor 200 in accordance with one embodiment of the present invention. In one embodiment, a CMOS image sensor formed on epitaxial silicon. A semiconductor substrate 205 has a front surface and a back surface. An array of photo-sensitive pixels 212 and MOS 208 are formed in and on the substrate 205. A conductive wiring pattern 250 is formed over the array of photo-sensitive pixels and within at least one isolation layers 222. An IR filtering coating is formed on the front side of the substrate 205 to act as an infrared ray filter to omit additional filter. One example is carbon nanotube (CNT) transparent conductive coating 220. A color filter array maybe necessary, and micro-lens 240 are fabricated over top of CNT 220. The micro-lens 240 serves to focus light into individual pixels. An exemplary film thickness of the CNT is less than ten microns. An exemplary types of CNTs such as single walled CNTs, double walled CNTs, and multi-walled CNTs. The electrical and optical properties of CNT will thus depend on its thickness, CNT diameter.

In one example, the conductive wiring pattern 250 is formed with CNT to increase the fill fact and an IR filter. In one embodiment a CMOS image sensor has a CNT to act as an optical filter for infrared radiation, thereby eliminating the need for a separate infrared filter. The response of silicon has a peak at about 750 nm but extends out in the near infrared to about 1,100 nanometers. It is therefore desirable to filter out wavelengths in the near infrared that are within the spectral response of the image sensor. It will also be understood that it is contemplated that in one implementation CNT coating layer 220 has optical characteristics selected to serve as a filter for a deleterious optical wavelength band to reduce the amount of filtering required by a separate optical filter. If the IR filtering coating 220 is employed, the additional IR filter is not required. However, if the conductive wiring pattern 250 is not formed with CNT, transparent conductive polymer, ITO or the combination, the fill fact will not be improved. In one example, the CNT transparent coating 220 maybe formed under the lens 240 or over the lens 240. The IR filtering coating 220 is formed with CNT, graphene or the combination. The at least one conductive pattern 250 is formed with carbon nano-tube, graphene or the combination to increase the fill factor.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. It is intended that the following claims and their equivalents define the scope of the invention.

What is claimed is:

1. An image sensor comprising:
a substrate;
a MOS having gate dielectric layer, a source, a drain and a gate, said MOS being formed over said substrate;
a photo-diode doped region formed adjacent to said MOS;
at least one isolation layer laminated over said photo-diode doped region;
at least one conductive pattern formed within said at least one isolation layer; and
an infrared ray filtering layer formed over said at least one isolation layer to act as an infrared ray filter, wherein said infrared ray filtering layer is formed with carbon nano-tube, graphene or the combination.

2. The image sensor of claim 1, wherein said at least one conductive pattern is formed with carbon nano-tube, graphene or the combination to increase fill factor.

3. The image sensor of claim 2, wherein said at least one conductive pattern further includes conductive polymer.

4. The image sensor of claim 1, further comprising lens formed over said at least one isolation layer to guide incident light into said photo-diode doped region.

5. An image sensor comprising:
a substrate;
a MOS having gate dielectric layer, a source, a drain and a gate, said MOS being formed over said substrate;
a photo-diode doped region formed adjacent to said MOS;
at least one isolation layer laminated over said photo-diode doped region;
at least one conductive pattern formed within said at least one isolation layer; and
lens formed over said at least one isolation layer to guide incident light into said photo-diode doped region;
an infrared ray filtering layer formed over said at least one isolation layer to act as an infrared ray filter, wherein said infrared ray filtering layer is formed with carbon nano-tube, graphene or the combination.

6. The image sensor of claim 5, wherein said at least one conductive pattern is formed with carbon nano-tube, graphene or the combination to increase fill factor:

7. The image sensor of claim 6, wherein said at least one conductive pattern further includes conductive polymer.

8. An image sensor comprising:
a substrate;
a MOS having gate dielectric layer, a source, a drain and a gate, said MOS being formed over said substrate;
a photo-diode doped region formed adjacent to said MOS;
at least one first isolation layer laminated under said substrate;
at least one conductive pattern formed within said at least one first isolation layer; and
at least one second isolation layer formed over said photo-diode doped region;
an infrared ray filtering layer formed over said at least one isolation layer to act as an infrared ray filter, wherein said infrared ray filtering layer is formed with carbon nano-tube, graphene or the combination.

9. The image sensor of claim 8, wherein said at least one conductive pattern is formed with carbon nano-tube, graphene or the combination to increase fill factor.

10. The image sensor of claim 9, wherein said at least one conductive pattern further includes conductive polymer.

11. The image sensor of claim 8, further comprising lens formed over said at least one isolation layer to guide incident light into said photo-diode doped region.

12. An image sensor comprising:
a substrate;
a MOS having gate dielectric layer, a source, a drain and a gate, said MOS being formed over said substrate;
a photo-diode doped region formed adjacent to said MOS;
at least one first isolation layer laminated under said substrate;
at least one conductive pattern formed within said at least one first isolation layer; and
at least one second isolation layer formed over said photo-diode doped region;
lens formed over said at least one isolation layer to guide incident light into said photo-diode doped region;
an infrared ray filtering layer formed over said at least one isolation layer to act as an infrared ray filter, wherein said infrared ray filtering layer is formed with carbon nano-tube, graphene or the combination.

13. The image sensor of claim 12, wherein said at least one conductive pattern is formed with carbon nano-tube, graphene or the combination to increase fill factor.

14. The image sensor of claim 13, wherein said at least one conductive pattern further includes conductive polymer
